(19) United States
(12) Patent Application Publication
(10) Pub. No.: US 2025/0363155 A1
(43) Pub. Date: Nov. 27, 2025

(54) Scoring and Display of Results of User Assessment Based on Simulated Interactions

(71) Applicant: INTERACTIVE EQ, Inc., Bell Canyon, CA (US)

(72) Inventor: Zhobin Napoleon Rumteen, Bell Canyon, CA (US)

(21) Appl. No.: 19/217,826

(22) Filed: May 23, 2025

Related U.S. Application Data
(60) Provisional application No. 63/679,910, filed on Aug. 6, 2024.

(30) Foreign Application Priority Data
May 24, 2024 (IN) 202411040382

(51) Int. Cl. G06F 16/334; G06F 16/3329

(52) U.S. Cl. CPC G06F 16/3347; G06F 16/33295

(57) ABSTRACT

A system determines scores for evaluating users for assessment. The system receives a plurality of responses from a user based in interactions based on a simulated meeting with the user. The system stores a plurality of expected responses. For each response received from the user, the system determines a plurality of raw metrics. Each raw metric evaluates the user based on the response by comparing the response received from the user with the expected responses stored in the database. The system determines a plurality of scores, each score i determined as a weighted aggregate of a set of raw metrics, each score evaluating the user. The system configures a second user interface for presenting the plurality of scores. The second user interface displays associations between a particular score and portions of response determined to be relevant for determining at least a raw metric considered for evaluating the score.

### CROSS-REFERENCE TO RELATED APPLICATIONS

This application claims the benefit of Indian Provisional Application No. 202411040382, filed on May 24, 2024, and also claims the benefit of U.S. Provisional Application No. 63/679,910, filed on Aug. 6, 2024, each of which is hereby incorporated by reference in its entirety.

### FIELD OF INVENTION

This disclosure relates generally to artificial intelligence techniques is general, and more specifically to performing simulated interactions based on an execution plan for evaluation of users using machine learning based language models.

### BACKGROUND

Organizations need to evaluate people, for example, potential members of the organizations. For example, employers need to evaluate users as potential employees. Certain portions of the evaluation are highly objective, for example, technical skills. These evaluations can be performed using standard questions sets that evaluate domain specific skills. However, it is difficult to evaluate soft skills, for example, how a user handles stressful situations or how the user reacts emotionally to certain situations. Evaluation of such soft skills is subjective and can be highly subjective and varies based on judgement or perception of different people evaluating the user. Conventional techniques for evaluating such skills of users include in person meetings in various contexts to observe how the user performs in these contexts or recording interactions with the user and analyzing various portions of the recordings. However, these techniques often provide inaccurate results and may arrive at incorrect conclusions about the user due to the subjective nature of the evaluation. Other techniques include using artificial intelligence techniques (AI) such as generative AI to build videos to interact with the user and use the interactions with the user for evaluation. Such techniques present an unnatural environment for interacting with the user since the user can recognize that the interaction is with an AI based bot and that may influence the users thinking and interactions, thereby influencing the outcome of the evaluation. Inaccurate evaluation of a user can have significant impact on the organization since recruiting an unsuitable user can be expensive for the organization and on the other hand the organization may lose suitable users.

### SUMMARY

The system according to various embodiments performs multi-module based integrated assessment of users. The system performs interactions with the user that represent an interview with a simulated experience. The system performs various interviews of the user including one or more of (1) electronic mail (email) based interview, (2) a chat-based remote meeting, and (3) an in-person video meeting based simulated experience. Various other types of interactions may be performed with the user. The system extracts signals from the interactions performed with a user using the various interviews and uses various analysis techniques including artificial intelligence based techniques to evaluate soft skills of the user.

According to an embodiment, the system receives information describing a user, for example, the name of the user, a profile picture of the user, and so on. The user represents a candidate or a talent that is being assessed. The terms user, candidate, and talent may be used interchangeably herein. The system configures a user interface for performing interactions with the user and causes the user interface to display via a device associated with the user. The system stores in a database, a plurality of media objects. A media object may store one or more of text data, video data, or audio data. The system retrieves an execution plan for a simulated interaction. The execution plan comprises a sequence of stored media objects.

The system performs via the user interface, interactions with the user using one or more channels. Some of the interactions comprise sending, via a channel, information describing a case study according to the execution plan, and receiving via the channel, a response from the user. The system captures information describing delivery of the response by the user via the channel while receiving the response. For example, the time taken by the user for delivering the response, whether the user modified the response before submitting it, and so on. The system determines a set of metrics based on responses received from the user and information describing delivery of the response by the user. The metrics evaluate the user. The system takes actions based on the metrics. For example, the system may configure a second user interface for presenting metrics and send the second user interface for display via a second device.

According to an embodiment, the system stores a plurality of video segments in a database. The system retrieves an execution plan for a simulated interaction with a user. The execution plan comprises instructions for a plurality of video interactions. Each video interaction comprises either displaying one or more pre-recorded video segments selected from a plurality of pre-recorded video segments or a live video stream of the user. The system repeatedly performs the following steps according to the execution plan of the simulated interaction. The system performs a sequence of video interactions. A video interaction may comprise selecting a set of pre-recorded video segments according to the execution plan and sending the set of pre-recorded video segments for display simultaneously via a user interface. In response to the sequence of video interactions, the system performs a second video interaction comprising, recording a live video stream of the user and storing the live video stream. The system analyzes the simulated interaction to evaluate the user and sends a recommendation based on the evaluation of the user.

According to an embodiment, the system uses a machine learning based language model for performing assessments of users. The system stores in a database, a plurality of media objects. Each media object comprises one or more of text data, video data, or audio data. The system retrieves an execution plan for a simulated interaction. The execution plan identifies a sequence of stored media objects for presentation to a user for performing the simulated interaction with the user. The system performs interactions with a user via one or more channels. An interaction may transmitting information describing a situation in accordance with the execution plan to a device of the user. An interaction may receive a response from the user based on the situation. The system generates one or more text inputs, for example, prompts for a trained neural network, for example, a machine learning based language model to evaluate the response. The text inputs comprise: a text representation of a response received from the user, information describing delivery of the response by the user, and a request to evaluate the user based on the responses received from the user. The system sends the text inputs to a trained neural network and receives responses generated by executing the trained neural network. The responses include information evaluating the user based on one or more criteria. The system determines metrics for evaluating the user based on the response received from the trained neural network and configures a user interface to present the metrics. The system causing the user interface to display on a device.

According to an embodiment, the system determines scores for evaluating users for assessment. The system retrieves a plurality of responses from a user, for example, a user based on the interactions with the user via a plurality of channels. The system stores in a database, a plurality of expected responses. Each set of expected responses may be associated with a scenario that may be presented to a user. The expected responses represents potential answers that a user may provide. For each response from the plurality of responses, the system determines a plurality of raw metrics. Each raw metric evaluates the user based on the response by comparing the response received from the user with the expected responses stored in the database. The system determines a plurality of scores based on the plurality of raw metrics. Each score is determined as a weighted aggregate of a set of raw metrics, each score evaluating the user. The system configures a second user interface for presenting the plurality of scores. The second user interface displays associations between a particular score and portions of response determined to be relevant for determining at least a raw metric considered for evaluating the score. The system sends the second user interface for display via a second device, for example, to a user evaluating the assessment of the user.

Embodiments include above described computer-implemented methods. Embodiments of a computer readable storage medium store instructions for performing the steps of the above computer-implemented methods. Embodiments of the computer system comprise one or more computer processors and a computer readable storage medium store instructions for performing the steps of the above methods.

The features and advantages described in this summary and the following detailed description are not all-inclusive. Many additional features and advantages will be apparent to one of ordinary skill in the art in view of the drawings, specification, and claims hereof.

### BRIEF DESCRIPTION OF THE DRAWINGS

The teachings of the embodiments can be readily understood by considering the following detailed description in conjunction with the accompanying drawings.

FIG. 1 is a block diagram of a system environment for performing user assessment, in accordance with an embodiment.

FIG. 2 is the overall process of performing user assessment, according to an embodiment.

FIG. 3A shows a screenshot of an interview representing a simulated remote meeting with the user, according to an embodiment.

FIG. 3B shows the components of a user interface for conducting a simulated online meeting, according to an embodiment.

FIG. 4 shows a screenshot of a simulated in-person meeting with the user, according to an embodiment.

FIG. 5 is a flowchart illustrating an execution of a simulated video meeting for evaluating the user, according to an embodiment.

FIG. 6 is a flowchart illustrating the use of machine learning based language models for performing assessments of users, according to an embodiment.

FIG. 7 illustrates scoring of a user for performing user assessment, according to an embodiment.

FIG. 8 is a flowchart illustrating the scoring of user responses for performing assessments of users, according to an embodiment.

FIG. 9 shows a screenshot of a user interface displaying various scores of the user and details of a simulated meeting, according to an embodiment.

FIG. 10 shows a screenshot of a user interface displaying various scores and raw metrics and their relations, according to an embodiment.

FIG. 11 is a high-level block diagram illustrating an example of a computer for use as one or more of the systems illustrated in FIG. 1, according to one embodiment.

The figures depict various embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

A system performs interactions with a user using one or more channels, for example, email, video, online chat, and so on and gathers information from the user. The system uses the information to evaluate the user. The system evaluates specific skills of user. For example, the system may evaluate soft skills of the user such as teamwork, problem solving, creativity, confidence, organization, cultural fit, flexibility, empathy, communication skills, adaptability, critical thinking, ability to resolve conflicts, and so on. Soft skills differ from hard skills such as technical abilities that may be evaluated by asking technical questions that may be evaluated on the basis of accuracy of the answers. Soft skills are difficult to evaluate since they may be indicated by factors other than the answer provided by the user, for example, a soft skill may be determined based on a delivery of the answer by the user. The system monitors the behavior of a user, for example, the delivery of the answer by the user. For example, the system monitors a degree of confidence in the user while providing a response based on the number of times the user modified the response before submitting the response via a user interface. The system uses artificial intelligence techniques, for example, language models to evaluate the user. The system provides feedback describing the user, for example, by displaying the score or by providing a recommendation. A user may also be referred to herein as a candidate or a talent. The techniques disclosed apply to various stages of a user's journey, for example, interview, review, performance enhancement in case of issues, and so on.

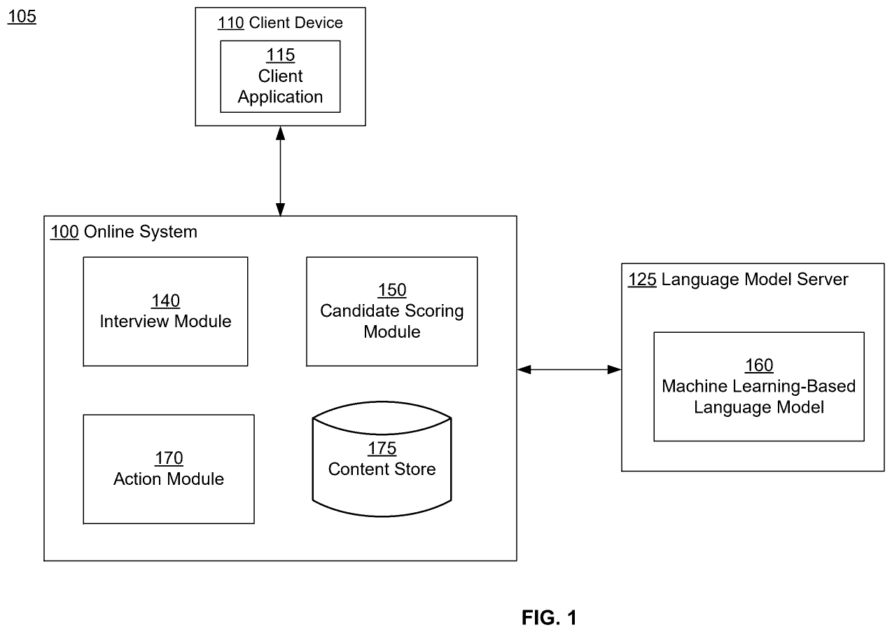

FIG. 1 and the other figures use like reference numerals to identify like elements. A letter after a reference numeral, such as “110A,” indicates that the text refers specifically to the element having that particular reference numeral. A reference numeral in the text without a following letter, such as “110,” refers to any or all of the elements in the figures bearing that reference numeral (e.g. “110” in the text refers to reference numerals “110a” and/or “110n” in the figures).

### System Environment

FIG. 1 is a block diagram of a system environment for performing user assessment, in accordance with an embodiment. The system environment 105 comprises the online system 100, one or more client devices 110, and a language model server 125. Other embodiments may have more of fewer systems within the system environment 105. Functionality indicated as being performed by a particular system or a module within a system may be performed by a different system or by a different module than that indicated herein. The online system 100 may also be referred to herein as a system.

A network (not shown in FIG. 1) enables communications between various systems within the system environment 105, for example, communications between the client device 110 and the online system 100, communications between the data sources 120 and the online system 100, and so on. In one embodiment, the network uses standard communications technologies and/or protocols. The data exchanged over the network can be represented using technologies and/or formats including, the HTML, the XML, JSON, and so on.

Although embodiments are described using an online system 100, the techniques disclosed herein can be executed using an offline system. For example, the instructions for executing the simulated set of user interactions may be stored on an offline computer and executed by a user. Information describing the user interactions are stored in the device and may be provided to a system that performs analysis at a later stage.

The online system 100 interacts with a user, for example, a user via the client device 110. The system environment 105 may include multiple client devices 110. A client device 110 is a computing device such as a personal computer (PC), a desktop computer, a laptop computer, a notebook, or a tablet PC. The client device 110 can also be a personal digital assistant (PDA), mobile telephone, smartphone, wearable device, etc. The client device 110 can also be a server or workstation within an enterprise datacenter. The client device executes a client application 115 for interacting with the online system 100, for example, a browser. Although, FIG. 1 shows two client devices, the system environment 105 can include many more client devices 110.

The client application 115 running on the client device is configured to display textual or video information to the user and allows the user to provide input as text, audio, or as video. For example, the client device may include a microphone to record audio input from the user and/or a camera to record video signal in addition to a keyboard for providing text input. According to an embodiment, the online system 100 presents results of evaluation of a user to another user, for example, an expert user who evaluates the user. The client device of the expert user is different from the client device of the user. A sequence of interactions performed with the user is also referred to herein as an assessment.

The online system 100 comprises modules including an interview module 140, a candidate scoring module 150, and an action module 170. Other embodiments can include more or fewer modules in the online system 100. Actions performed by a particular module may be performed by other modules than those indicated herein. Furthermore, the modules may be distributed across multiple processors or computing systems, for example, the interview module 140 may execute on one computing system while the candidate scoring module 150 may execute on another computing system.

The interview module 140 performs interactions with a user that represent interviews of the user. The interview module 140 performs interactions via one or more channels. Each channel is configured to perform interactions with the user. A channel can present information to the user and request user to provide a response. The channel further receives responses provided by the user. Examples of channels used by the system 100 include video channel, audio channel, chat, email, and so on. For example, the interview module 140 may provide a scenario or a problem as a video presented via a video channel, as an audio signal presented via an audio channel, as a text message presented via an email or a chat interface. A message may also be referred to herein as a communication. A chat interface may also be referred to herein as a chatbot, an interactive messaging channel, an interactive text communication channel, an interactive messaging interface, or a messaging interface. A scenario may also be referred to herein as a case study, a situation, a workflow example, or an equivalent term. The response from the user may be received synchronously or asynchronously. For example, a video channel may present a video and request a response form the user within a threshold time interval after the presentation of the video. Accordingly, the system 100 is blocked waiting for the response of the user after presenting the request. In contrast, the interview module 140 may send a text message via email such that the user can provide the response at any point later. The system 100 is not blocked waiting for the user's response via an email. The interaction via a chat interface is performed synchronously. An audio channel may operate synchronously or asynchronously.

The system performs simulated meetings or simulated interactions with the user. The simulated meetings are conducted based on a predefined script that presents a particular situation or scenario to the user and is designed to evoke a particular response from the user or test specific behavioral attributes or soft skills of the user. For example, a script may present a simulated meeting in which one or more simulated characters are having a conflict so that the system can monitor how the user responds to the conflict or how the user attempts to resolve the conflict. Some of the interactions between the simulated characters may be implicit based on their facial expressions and may not involve specific verbal interactions. The system stores metadata describing the soft skills or behavioral attributes of the user that need to be monitored at specific points in time in the script and monitors behavior of user and stores information describing the user's responses. The system monitors whether the user is able to determine the presence of a conflict and whether the user event attempts to resolve the conflict. The manner in which the user responds in this scenario contributes to calculation of particular score values or metrics assigned to the user and determine the user's assessment.

According to an embodiment, the system performs an online simulated meeting in which the simulated participants and the user are interacting remotely. Accordingly, each simulated participant is shown as a separate video of an online meeting, for example, a zoom meeting. Alternatively, the system may simulate an in-person meeting in which a video is presented to the user showing multiple participants in a room. The user is simulated as being a participant who is present in the room with the other participants. The in-person meeting may include one or more remote participants. The types of scenarios that may be presented in an in-person simulated meeting may be different from the types of scenarios presented in an online meeting and are used to measure metrics different from those measured

According to an embodiment, the system synchronizes the timing of information across multiple channels in accordance with an execution plan corresponding to a script for a simulated meeting or a simulated interaction, for example, a simulated online interaction. For example, the system may send a message via a chat interface while a particular video is being presented to the user. The timing may be orchestrated so as to test certain reaction from the user. For example, the system may monitor whether the user responds to the chat interface while watching a person talk on the video or while the user is speaking via a live video stream. Such response may be used to determine specific soft skills such as ability to multitask, effectiveness in handling multiple situations at the same time, or ability to respond during a stressful situation.

The content store 175 stores content used for performing interactions with the user. The content includes text snippets used for composing emails to the user, questions for asking the user via a chat interface, or video segments for use in a simulated video meeting with the user. The content store 175 may also store a script for an interaction with the user, for example, a script identifying various video segments to present to user and the order in which the video segments are presented.

The interview module 140 performs interactions in accordance with a predefined script. For example, the interview module 140 selects videos stored in the content store 175 and presents them to the user according to the script. Alternatively, the interview module 140 may access questions in text form and ask the user via an email channel or via a chat interface. The interview module 140 receives the responses from the user and stores the responses. The interview module 140 provides information describing the interactions with the user including the responses to the user scoring module 150.

The candidate scoring module 150 receives the interactions with the candidate performed by the interview module 140 and evaluates the candidate by scoring the candidate. The candidate scoring module 150 may interact with the language model server 125 to evaluate the candidate for various behavioral attributes indicative of soft skills.

The action module 170 performs an action based on the analysis performed by the candidate scoring module 150. For example, the action module 170 may configure a user interface to display one or more scores indicating soft skills of the user based on the user interactions. The action module 170 may store information indicating the evaluation in a database, for example, a database storing information of various users. The action module 170 may schedule a meeting associated with the user, for example, a meeting to review the results of evaluation of the user or a subsequent meeting with the user. Accordingly, the action module 170 may invoke an API or a calendar application or a server to add a calendar entry. The action module 170 may send a recommendation to a user for taking subsequent action, for example, by automatically generating and sending an email. The action module 170 may automatically generate a report associated with the user and send to another user evaluating the user.

The online system 100 may interact with a language model server 125 that executes a machine learning-based language model 160, for example, a large language model. A machine learning based language model may be a trained neural network. For example, the online system 100 may generate a prompt comprising information describing a candidate and send the prompt to the language model server 125. A prompt may also be referred to herein as a natural language request for a machine learning based language model. The language model server executes the machine learning-based language model 160 using the prompt to generate a response and provides the response to the online system 100. The machine learning-based language model 160 may be invoked by the interview module 140 or by the candidate scoring module 150. In an embodiment, the machine learning-based language model 160 is a large language model (LLM) that is trained on a large corpus of training data to generate outputs for natural language processing tasks. An LLM may be trained on massive amounts of text data, often involving billions of words or text units. An LLM may be trained on a large amount of data from various data sources, for example, websites, articles, posts on the web, and so on. An LLM may have a significant number of parameters in a neural network (e.g., transformer architecture), for example, several billion or even over a trillion parameters. In one instance, the LLM may be trained and deployed or hosted on a cloud infrastructure service. According to an embodiment, the LLM has a transformer-based architecture, for example, an encoder-decoder architecture and includes a set of encoders coupled to a set of decoders. While an LLM with a transformer-based architecture is described as an embodiment, it is appreciated that in other embodiments, the language model can be configured as any other appropriate architecture including, but not limited to, long short-term memory (LSTM) networks, Markov networks, BART, generative-adversarial networks (GAN), diffusion models (e.g., Diffusion-LM), and the like.

According to an embodiment, the interview module 140 performs different types of interactions with the user. Examples of different types of interactions include (1) electronic mail (email) based simulation in which email communications are used for interacting with the user, (2) a chat-based remote meeting simulation in which online chat is used for interacting with the user, and (3) an in-person video meeting simulation in which an interactive video is used for simulating an in-person interview with the candidate. Various other types of interactions may be performed with the candidate. An interaction may result in receiving input from the candidate in a particular media form, for example, audio, video, or text. An audio input received from the candidate may be transcribed into text form. Similarly, audio may be extracted from a video input and transcribed into text form. The various types of input received by the interview module 140 is provided to the candidate scoring module 150 for generating scores for the candidate. The scores of the candidate are used for evaluating (i.e., assessing) the candidate. The candidate assessment may be an ongoing process that is executed as the interview module 140 interacts with the candidate and obtains input from the candidate. The assessment of a particular portion of the interview may affect the types of interactions performed with the user subsequently by the interview module 140.

According to an embodiment, an interaction performed by the interview module 140 may present a particular situation, for example, a real-life situation associated with an organization to the candidate and requests the candidate to respond with an answer indicating how the candidate would handle the situation.

According to an embodiment, the interview module 140 monitors various aspects of the user interaction including the substantive response provided by the user as well as information describing how the user responded. Such information includes various attributes of the user interaction including the amount of total time taken by the user to respond, the time taken by the user for various portions of the response, a measure of an amount of revisions performed by the user (for example, by deleting text that was previously provided and/or by editing the text provided by the user as part of the response), whether the user was hesitating while typing as indicated by a user going back and forth between different portions of the response while providing the response, whether the user was copying from one portion to another, and so on. The online system 100 presents a client application 115 to the user that includes a text editor that is used by the user to provide a response. The online system 100 receives the information describing how the user provided the response by monitoring the user interactions with the text editor. This information may be user by the candidate scoring module 150 the evaluate attributes of the user, for example, confidence level of the user. Information such as the time taken to provide the response is used by the online system 100 to measure attributes of the candidate such as efficiency.

The candidate scoring module 150 considers substantive aspects of the user response, for example, a level of understanding of the user of the situation, a quality of response provided by the candidate, the quality of writing of the user, and so on. According to an embodiment, the online system uses machine learning based language models, for evaluating the natural language-based responses received from a candidate.

According to an embodiment, the online system stores information in a vector database. The online system encodes the information into embeddings and stores the embeddings in a vector database, for example, a structured index for processing in conjunction with the LLM. Examples of structured indexes include GPT-Index, LlamaIndex, or LangChain. According to an embodiment, the online system 100 receives user feedback from experts that monitor the evaluation of candidates performed by the online system 100 and provide feedback on the candidate assessments so that the feedback is used for training the LLM used by the online system 100.

According to an embodiment, the interview module 140 performs interactions with a candidate representing interviews with simulated experiences representing different types of meetings to evaluate the candidate. An example meeting is an internal meeting within the organization, where the simulated participants of the meeting are all members of the organization. Another example meeting involves a scenario with people outside the organization, for example, external people such as clients/customers of the organization. The candidate's interactions in various scenarios are monitored and used to assessment of the candidate.

According to an embodiment, a user interaction with a candidate proceeds as follows. The candidate is sent an email with a link. The candidate uses the link to connect to the online system 100 and authenticate with the online system 100. The candidate is provided high level instructions about the interview simulation, for example a brief description of a scenario, the time allotted to the simulation, and so on. The candidate starts the interview simulation. The candidate may be provided an email thread. The candidate is requested to review and analyze the email thread and prepare a response.

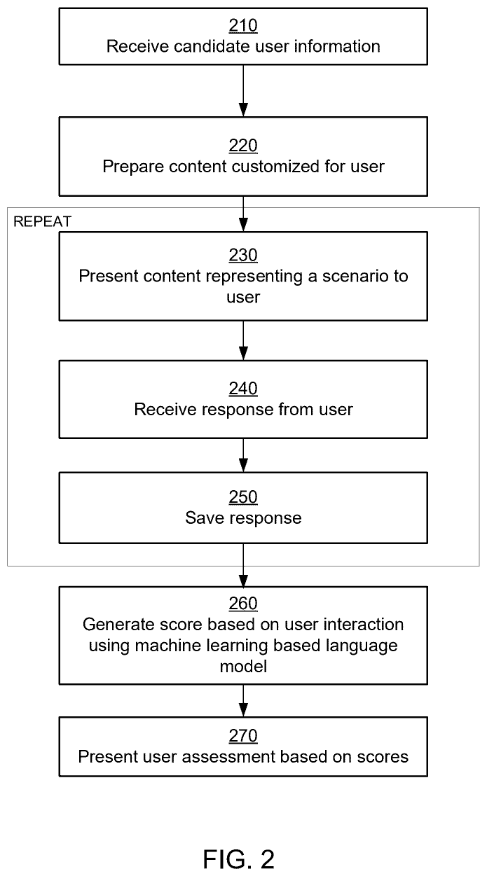

FIG. 2 is the overall process of performing candidate assessment, according to an embodiment. The steps are indicated as performed by a system and may be performed by modules of the online system 100. The steps of the process may be performed in an order different from that indicated herein. Some of the steps may be treated as optional.

The system receives 210 information describing the candidate who is being assessed. The information may include the name of the candidate, contact information of the candidate, for example, email, and optionally an access to public information of the user. The access to public information of the user may be provided as a URL (uniform resource locator) of a public social media profile posted on a professional network, for example, a LinkedIn™ profile. According to an embodiment, the system access the URL of the public social media profile to retrieve information, for example, a profile picture of the candidate.

The system prepares 220 content that is customized for the candidate. For example, the system may modify text of the questions to use the name of the candidate. The system may modify the audio within a video to use the name of the candidate. Accordingly, the content stored in the content store 175 is treated as template with placeholders that are replaced with actual candidate information. The placeholder in the content stored in content store 175 may use names of a hypothetical candidate, for example, a question may use name of a hypothetical user Johnathan such as “Johnathan, how would you handle this situation?” If the system receives a user named David, the system modifies the question to use the candidate name by replacing the name of the hypothetical user with the name of the candidate to arrive at the question, “David, how would you handle this situation?” The question may be asked via a chat interface, via email, or may be part of the audio of a video segment. According to an embodiment, the system performs text modification by replacing placeholder information with actual candidate information via text replacement. Alternatively, the system uses a machine learning based model that processes audio input to modify the audio input to replace placeholder information with candidate information. The machine learning based model is trained to receive as input a audio signal representing the content to be modified and candidate information and generates modified audio signal that uses the candidate information instead of a placeholder information of a hypothetical user.

According to an embodiment, the machine learning based model determined one or more audio characteristics of the name of the candidate used in the pre-recorded video are based on a context of the particular pre-recorded video. Examples of audio characteristics include a tone of the audio signal, a volume of the audio signal, a pitch of the audio signal, and so on. For example, the machine learning based model modifies the manner in which the candidate information is spoken based on a context of the audio signal. The manner in which the candidate information is spoken includes the pitch used in the audio signal while using the candidate information, the volume of the audio used for speaking the candidate information, and so on. For example, if the audio signal represents a tense situation to assess how calmly the candidate handles a particular situation, the candidates name is spoken in the modified audio signal differently from an audio signal in which various participants interacting in a less tense situation, for example, while introducing themselves.

The system may perform multiple interactions with the user. Each interaction may present a scenario or a particular situation in which the user is expect to provide answers or responses. The system may present the scenario by presenting 230 content representing the scenario to the candidate. The content representing the scenario may comprise a sequence of video segments that are presented to the user. The system may present a plurality of video segments simultaneously to simulate a meeting with multiple simulated participants. The system may present text snippets from various simulated participants to simulate a chat interaction between multiple participants including the candidate.

The system receives 240 one or more responses from the user. For example, for a simulated video meeting, the system receives the user response in the form of a live video from the user that is recorded and stores. Similarly, for a simulated interaction via chat interface, the system presents stored text snippets for the user indicated as messages from simulated users and receives text messages provided by the candidate and stores them. Similarly, for email interaction, the system receives an email response from the user and stores it. According to an embodiment, the system may store the entire transcript of the interaction performed with the user including the stored and generated content from the system and the live content received from the user in the order in which they were executed as part of the script.

According to an embodiment, the system records the manner in which the user provides the information. For example, if the user types in response as a text string via the chat interface, the system monitors secondary information such as the

The system generates 260 various scores based on the user interaction corresponding to each assessment performed with the user based on a scenario or a situation. According to an embodiment, the system provides information describing the interaction to a machine learning-based language model 160 in a prompt. The information describing the interaction includes the content provided by the system to the candidate, the responses provided by the candidate, and the secondary information representing the manner in which the user provided the content. The system requests the machine learning-based language model 160 in the prompt to evaluate the user responses based on various criteria indicating soft skills of the user. The system receives a response from the machine learning-based language model 160 and extracts various scores evaluating the user based on the various criteria. The system may take one or more actions as described in connection with the action module 170, for example, by presenting the scores of the user via a user interface.

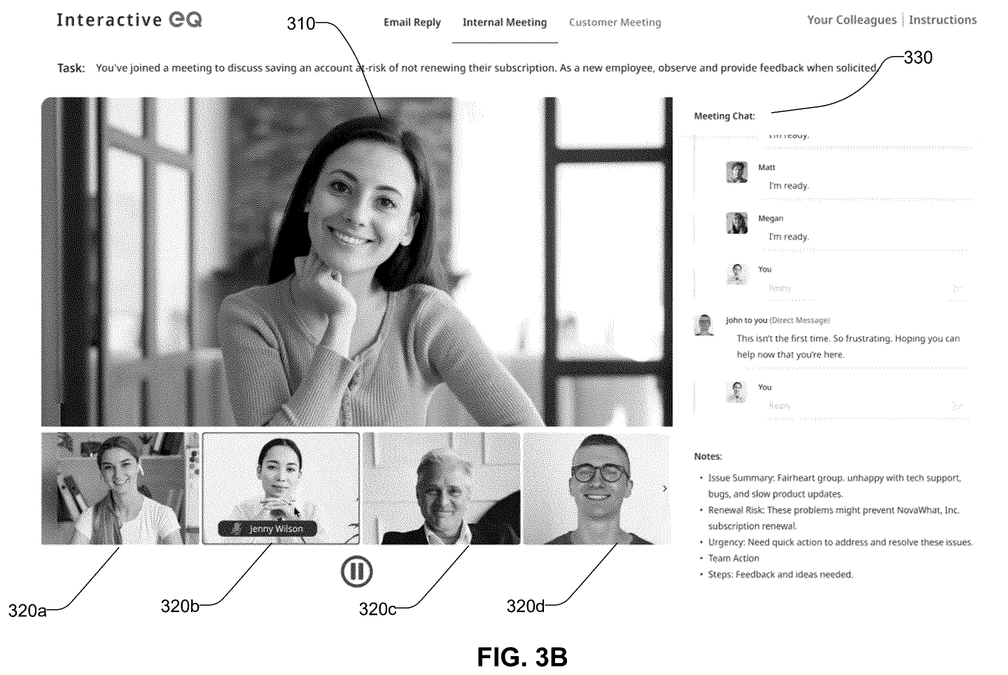

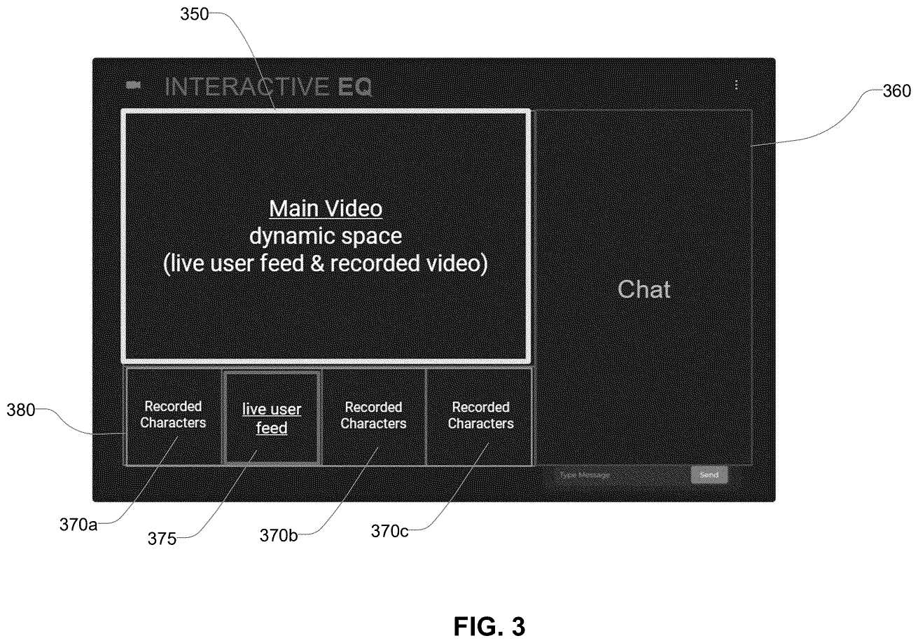

FIG. 3A shows a screenshot of an interview representing a simulated remote meeting with the user, according to an embodiment. The candidate may perform an interview with a simulated experience of a remote meeting using the user interface illustrated in FIG. 3A. According to an embodiment, the simulation provides a user interface of a video meeting such as a zoom meeting or a Webex meeting. A chat interface 330 may be provided in a panel within the user interface to allow the user to type in responses. The online system 100 may display participants of the meeting in the user interface. According to an embodiment, the live video stream of the candidate is included as a participant of the video conference call along with remaining participants that are simulated users that are pre-recorded characters. According, the online system 100 configures a user interface of a video conference that includes a set of simulated users based on pre-recorded characters including one user that is the candidate whose video represents a live video stream of the candidate.

According to an embodiment, the user interface presents a main video 310 along with one or more gallery videos 320a, 320b, 320c, 320d, 320e. The main video 310 is displayed larger than the gallery videos. According to an embodiment, the main video represents a simulated person that is currently speaking according to the script of the video meeting. Both the main video 310 and the gallery videos 320 may be prerecorded videos. A prerecorded video from the gallery may show a person who starts speaking and that video is moved to the frame of the main video and the video that was being played in the frame of the main video is moved to a frame of a gallery video. Accordingly, gallery videos may switch places with the main video. The frame of the main video may also be used to display a live video stream of the candidate when the candidate is responding. The live video stream is obtained from a camera, for example, a webcam or a camera of a client device of the candidate. The live video stream is recorded and stored as a video that is subsequently analyzed.

The video of the user that is currently speaking is moved to a larger panel as the main speaker, whether the video is a pre-recorded video of a simulated character or whether the video is live stream of the candidate. According to an embodiment, the online system 100 modifies the audio signal generated for various simulated characters to use the actual name of the candidate. Accordingly, the pre-recorded audio signal includes place holders where the audio signal is edited to include the candidate's name. Accordingly, the user interface provides an immersive and interactive interview experience for the candidate. The user interface includes a chat portion where the candidate may use the chat for interacting with various participants of the simulated video conference call. The system provides the text input received from the candidate via the chat interface as well as audio input received from the candidate transcribed to text data for providing to an LLM for candidate assessment.

According to an embodiment, the online system 100 stores various videos for each simulated character that is a participant in the meeting. The online system 100 times the different videos and interleaves their presentation so that the video of a user that is speaking is in a larger panel compared to the other participants. When a different participant starts speaking, the video in the large panel switches to the participant that is speaking. The participant may be one of the simulated participants or the candidate, i.e., the actual live participant.

FIG. 3B shows the components of a user interface for conducting a simulated online meeting, according to an embodiment. The user interface shows a frame of a main video 350 and one or more frames of gallery videos displaying recorded characters 370a, 370b, 370c. The main video 350 has a frame that is larger than the frames of individual gallery videos and may display a participant that is currently speaking. The main video may switch with a gallery video if the simulated character or the candidate displayed in the galley video starts speaking. The gallery videos may also include a live video stream 375 of the candidate captured from a camera mounted on a device used by the candidate. The various gallery videos 370 including the live video stream 375 may be combined into a single video 380 that is efficient to transmit, and display compared to several independent videos. The combined video 380 is included in the user interface and sent to the device of the candidate for display. According to an embodiment, the system displays a chat window 360 for displaying a chat session between the candidate and simulated participants. The messages displayed on the chat window are synchronized with respect to the videos displayed in the frames of main videos 350 and gallery videos 370 so as to create specific scenarios based on a combination of the video interaction and the text-based interaction via chat. This allows the system to monitor the candidate's behavior wile handling multiple interactions via two distinct channels.

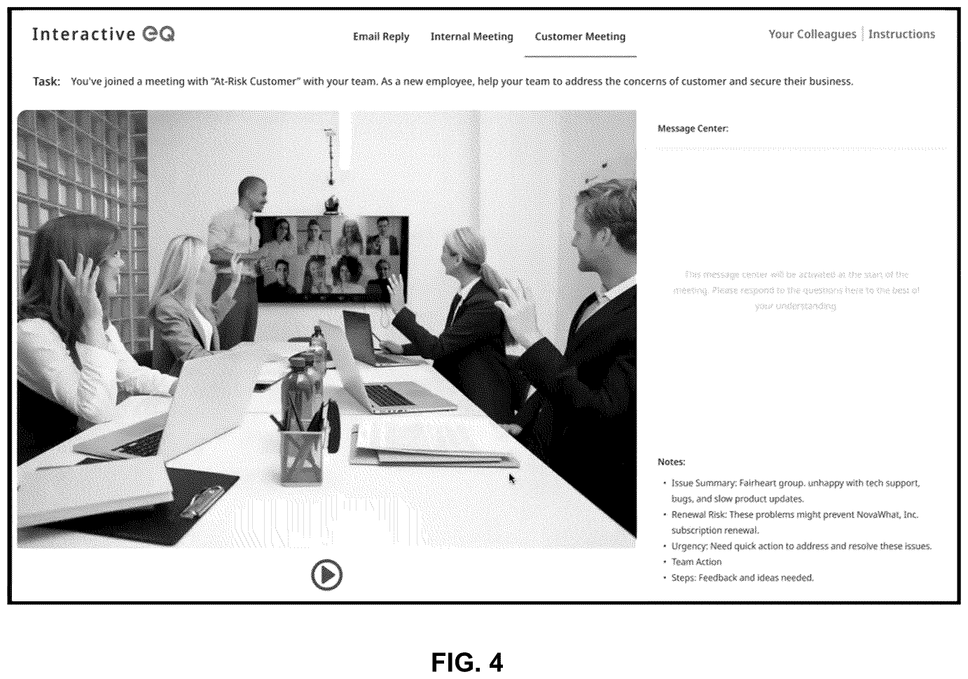

FIG. 4 shows a screenshot of a simulated in-person meeting with the user, according to an embodiment. The user interface provides an immersive experience of an in-person meeting that may involve participants from the organization and external participants (e.g., customers of the organization). According to an embodiment, the user interface presents a video that includes a monitor displaying remote participants of the meeting. The candidates video stream captured by the online system 100 is displayed as part of the video displayed in the monitor displaying remote participants of the meeting. Accordingly, the monitor presented within the video displays a remote participant's video that is enlarged if the remote participant is speaking (and small otherwise), independent of whether the remote participant is a simulated participant of the candidate who is a live participant. The audio provided by the candidate is transcribed to generate text that is provided to the LLM for candidate assessment.

According to an embodiment, the prerecorded interactions between participants of the in-person simulated meeting include various situations that are associated with candidate assessment. The online system 100 analyzes the candidate responses to determine whether the candidate was able to pick up on such situations and cues and responded appropriately. The online system 100 may also ask via a chat interface, various questions related to simulated participants in the simulated in-person meeting. According to an embodiment, the online system 100 analyzes the video of the candidate that is captured to monitor body language of the candidate, facial expressions and reactions of the candidate, hand movements, gestures performed by the user, and so on to evaluate emotional and other type of reaction based on machine learning based models that analyze the video. The analysis of the video stream of the candidate is provided as input to the candidate scoring module 150 for use in evaluation of the candidate.

According to an embodiment, the information used for assessment of the candidate is determined based on the location of the candidate or the location of the organization to conform with local laws and regulations. For example, if use of certain feature is prohibited or discouraged in a geographical region (for example, a state or country), the candidate scoring module 150 eliminates that feature from the calculation of the candidate assessment and performs the candidate assessment based on other features. According to an embodiment, the candidate scoring module 150 stores information describing local regulations/laws related to candidate assessment. The candidate scoring module 150 determines locations of the candidate and/or the organization that is interviewing the candidate and performs a lookup of the regulations/laws for the location to determine if the candidate scoring process needs to be adjusted in accordance with the local laws/regulations. If the candidate scoring module 150 determines that the candidate score determination depends on the local laws/regulations, the candidate scoring module 150 determines the candidate score in accordance with the local laws/regulations, for example, by eliminating certain features from the candidate assessment. The candidate scoring module 150 may eliminate certain features by forcing the weights of those features to zero while determining the candidate score.

### Orchestrating and Analyzing Simulated Video Meeting

The system performs simulated meetings where recorded videos are presented to the candidate and responses are received from the candidate and stored and analyzed for assessment of the candidate. For example, the system may store several hundred video segments. The system receives a script for the video meeting. The script describes what scenarios are presented to the candidate and corresponding questions asked to the candidate based on the scenario. The system receives an execution plan based on the script. The execution plan is a sequence of video interactions. A video interaction may either (1) present a set of prerecorded videos to the user or (2) receive a response from the candidate in the form of a live video stream that is recorded for analysis.

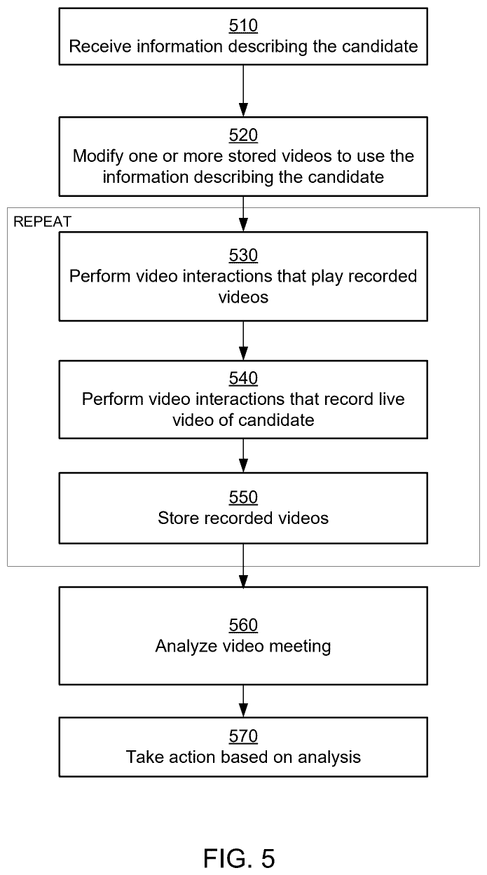

FIG. 5 is a flowchart illustrating an execution of a simulated video meeting for evaluating the candidate, according to an embodiment. The process may be executed by modules of a system, for example, online system 110. The steps may be performed in an order different from those indicated herein.

The system receives 510 information describing the candidate, for example, name of the candidate, a title of the candidate, and so on. The system modifies 520 one or more stored videos to customize them for the candidate, for example, modifying the audio of the video to use the name of the candidate instead of a placeholder name.

The system performs a sequence of video interactions with the user in accordance with the script. The sequence of video interactions form the video meeting with the user. A typical script performs 530 one or more video interactions that play prerecorded videos. For example, the video interaction may describe a scenario to the user. After playing the prerecorded videos the system performs 540 a video interaction in which at least a live video is played where the candidate provides a response based on the one or more video interactions. The system records 550 the live video stream presenting the response provided by the user.

A video interaction may display a plurality of videos as shown in the exemplary user interface of FIG. 3. The plurality of videos displayed may show a main video 310 that is typically shown larger than the remaining videos of the plurality. The remaining videos of the plurality of videos that are not the main video are referred to as gallery videos 320 and are displayed as smaller videos.

The system analyzes 560 the video meeting including the recorded video responses of the candidate. The system takes actions based on the analysis, for example, the various actions performed by the action module 170.

### Artificial Intelligence-Based Analysis of Candidate Responses

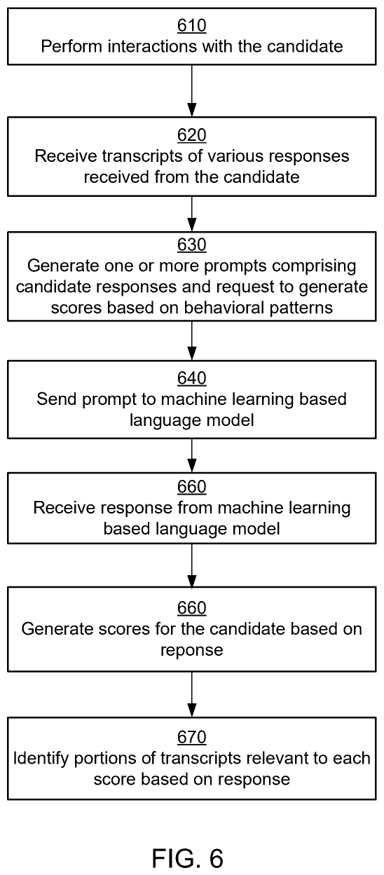

FIG. 6 is a flowchart illustrating the use of machine learning based language models for performing assessments of candidates, according to an embodiment. The process may be executed by modules of a system, for example, online system 110. The steps may be performed in an order different from those indicated herein.

The system performs 610 interactions with the candidate using one or more channels. The system receives 620 transcripts of various responses received from the candidate. A transcript of a response represents a textual representation or a text representation of the response. A response may be received in text form, for example, from a chat interface. Alternatively, a response may be received as media, for example, a video or audio file. The system may transcribe the audio or video signal to generate a response in text form.

The system generates 630 one or more prompts for a machine learning based language model. The prompt may include the response received from the user. The prompt may include a context of the response, for example, the scenario that was presented to the user for which the user provided the response. The prompt may include additional information describing the response, for example, a time taken by the user to provide the response, a number of times the candidate revised or modified the response before submitting the response, and so on. The system may identify situations where the candidate was expected to provide some response but failed to act and provide the corresponding information in the prompt. For example, the simulated interaction may generate a context in which it is optional for the candidate to provide a response. If the candidate provides the response, the response is included in the prompt. If the candidate decides not to provide any response given the context, the system indicates in the prompt that no response was provided by the user in the given context. The fact that the user chose to not act in a particular situation may be used by the system to determine scores based on behavioral traits of the candidate. According to an embodiment, certain attributes of the audio or video including changes in pitch of the voice of the user or changes in volume of the voice of the user are included in the prompt. The system may use changes in audio signal such as changes in pitch or volume as factors in scoring the candidate for specific behavioral traits. The system may include in the prompt, requests for the machine learning language model to evaluate the candidate based on specific behavioral traits such as situational awareness, behavioral recognition, issue recognition, sense of urgency, and so on. The system may include in the prompt, requests for the machine learning language model to identify portions of the response provided by the user that were used for determining the corresponding values of the scores.

The system sends 640 the prompt to the machine learning-based language model 160, for example, by transmitting the prompt to the language model server 125. The system receives 660 one or more responses from the machine learning based language model. The system generates scores for assessment of the candidate based on the responses received from the machine learning based language model. The system identifies the various portions of the transcript of the candidate responses considered by the machine learning based language model for determining various score values. The system may display the various scores and their associations with portions of the transcript of the candidate response used to determine the corresponding scores via a user interface.

According to an embodiment, the video segments may be generated using generative AI techniques such as text to video. A user inputs assessment details, for example, a story, scenarios or situations to focus on, various characters, and so on. The system uses generative AI techniques to generate a script based on the inputs. For example, the details specified by the user are included in a prompt along with a request to generate a script for presenting to a candidate. The prompt is provided as input to a machine learning-based language model that is executed to generate the script based on the prompt. The system uses AI avatars as characters to generate video segments of realistic characters based on the generated script. The video segments are used for simulated video meetings. The machine learning-based language model may be used for generating script for a chat interface that is used in a chat or an interactive communication channel along with a simulated video meeting or interview. The machine learning-based language model may be used for generating emails for sending to the candidate for evaluation via an email channel. The responses received from the candidate are used for assessment of the candidate, for example, by determining scores for evaluating the candidate as further described herein.

### Scoring for User Assessment

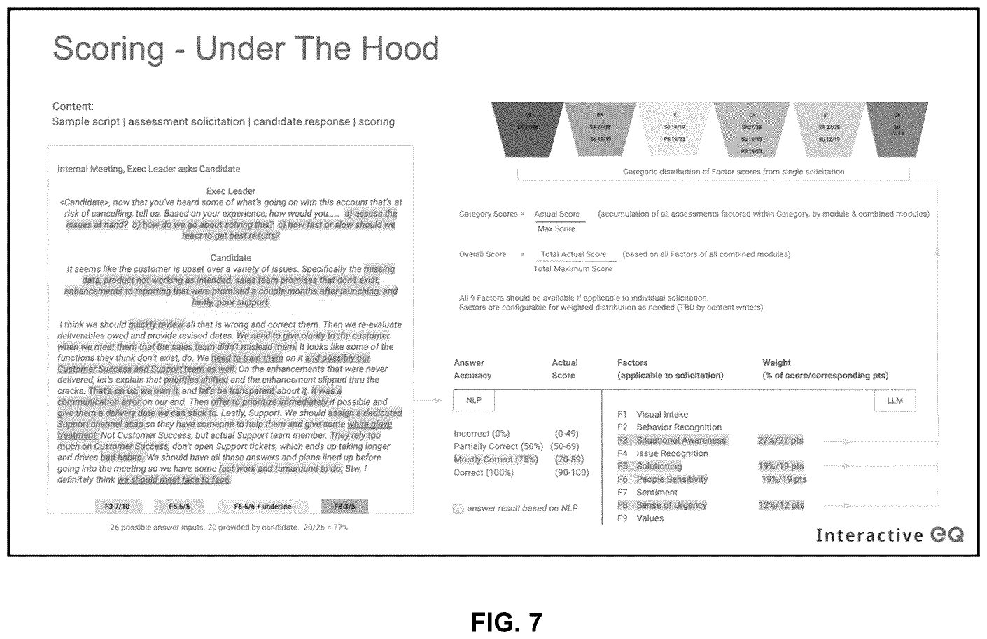

FIG. 7 illustrates scoring of a candidate for performing user assessment, according to an embodiment. According to an embodiment, the candidate scoring module 150 evaluates candidates based on a breadth of answers provided by the candidate as well as depth of answers provided by the candidate. For example, if the ideal response to a question is determined to address a number of issues, the candidate scoring module 150 may measure the breadth of the candidate's answer based on the number of issues that the candidate addressed in the response. The candidate scoring module 150 further measures the depth of the answer by analyzing the level of details provided by the candidate for each issue addressed by the candidate.

According to an embodiment, the candidate scoring module 150 evaluate answers provided by the candidate by considering a plurality of factors, for example, situational awareness, issue recognition, people sensitivity, sentiment, sense of urgency, and so on. The candidate scoring module 150 may use machine learning based language models to evaluate responses with respect to various factors. The candidate scoring module 150 determines factor score for each factor based on responses provided by the candidate. The candidate scoring module 150 aggregates the factor scores to determine an overall score representing the candidate's assessment.

FIG. 7 illustrates the responses provided by the user and the various factors considered by the candidate scoring module 150 for assessment of the candidate. According to an embodiment, the candidate scoring module 150 identifies various portions of the user response that contributed to a particular factor score. According to an embodiment, the candidate scoring module 150 displays via a user interface, the associations between various factors and the corresponding portions of user responses used to determine the factor scores for various factors. For each factor the candidate scoring module 150 may evaluate the factor based on the breadth of the candidate's response and the depth of the candidate response.

According to an embodiment, the candidate scoring module 150 groups factors into categories and determines scores for each category. The candidate scoring module 150 aggregates the category scores to determine the overall score for candidate assessment. Certain types of responses may improve the category score for a particular category (or factor score for a factor) and certain types of responses may decrease the category score for that category (or factor score for that factor).

The user interface shown in FIG. 7 relates various factors considered for the candidate assessment with the corresponding portions of the candidate's response used for determining that particular factor. The user interface may further display the score in each category or score for individual factors for the candidate to provide insights into how the overall score for the candidate was determined.

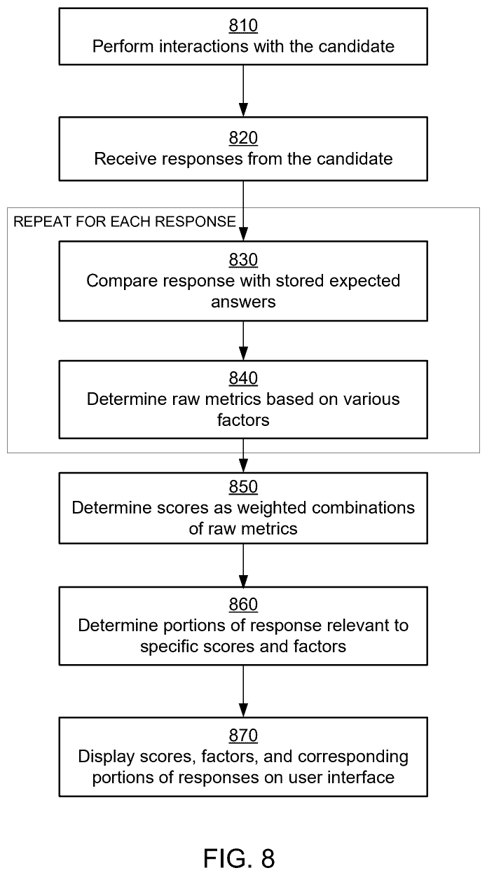

FIG. 8 is a flowchart illustrating the scoring of candidate responses for performing assessments of candidates, according to an embodiment. The process may be executed by modules of a system, for example, online system 110. The steps may be performed in an order different from those indicated herein.

The system performs 810 interactions with users via one or more channels and receives 820 responses from the candidate. The interactions represent solicitation by the system using a simulated meeting or interview to prompt verbal or text responses from the candidate. A response may determine how the candidate would handle a particular situation or scenario. A response may also be referred to herein as an answer. The system may receive responses from the candidate in various ways, for example, as candidate's voice, text input, or keyboard clicks, or mouse clicks. The system may convert various responses to a textual representation, for example, voice input may be converted into text using a speech to text converter.

The system stores expected answers or responses for various scenarios in a database. According to an embodiment, the system stores the expected answers (or expected responses) in a vector database as vector representations of the expected answers. The system can perform semantic match with expected answers by comparing a vector representation of a received response with vector representations of expected answers using a distance metric, for example, based on cosine similarity or any other similarity metric. Accordingly, the system analyses each response by repeating the following steps 830 and 840 for each response. The system compares 830 a response with stored expected answers. The system determines raw metrics evaluating the candidate based on various factors that represent behavioral characteristics or traits. For example, the raw metric may measure the quality of responses based on factor such as situational awareness, issue recognition, sense of urgency, visual intake, sentiment, and so on. Accordingly, each response from the candidate is assigned weights corresponding to various factor. These weights represent the raw metrics.

The system determines 850 scores measuring skills of the candidate, for example, soft skills based on the raw metrics. For example, the score for each soft skill is determined as a weighted aggregate of a set of raw metrics representing the above factors. Accordingly, scores are determined for various soft skills such as observation skills, business acumen, empathy, cultural fit, collaborative aptitude, and so on. For example, cultural fit score may be determined as a weighted aggregate of raw metrics measuring value, sense or urgency, and sentiment, whereas empathy may be determined as a weighted aggregate of raw metrics measuring people sensitivity, sentiment, and solutioning. The system may aggregate raw metrics across various responses received from the candidate. Similarly the system determines scores measuring soft skills across various responses received from the user.

The system also determines 860 the portions of responses that are relevant for determining specific scores or raw metrics. The system may determine the relevant portions of responses based on a machine learning-based language model. For example, the system may provide a response and identify specific raw metric in a prompt and request the machine learning-based language model to identify portions of the response relevant to the specific raw metric. The system receives the response by executing the machine learning-based language model and analyzes the response to extract the various portions of the response relevant to the specific raw metric. According to an embodiment, the system also requests the machine learning-based language model to determine a value of the specific raw metric based on the response. The system extracts the value of the raw metric based on the response of the machine learning-based language model. The system displays scores, raw metrics, and corresponding portions of responses obtained from the candidate on a user interface.

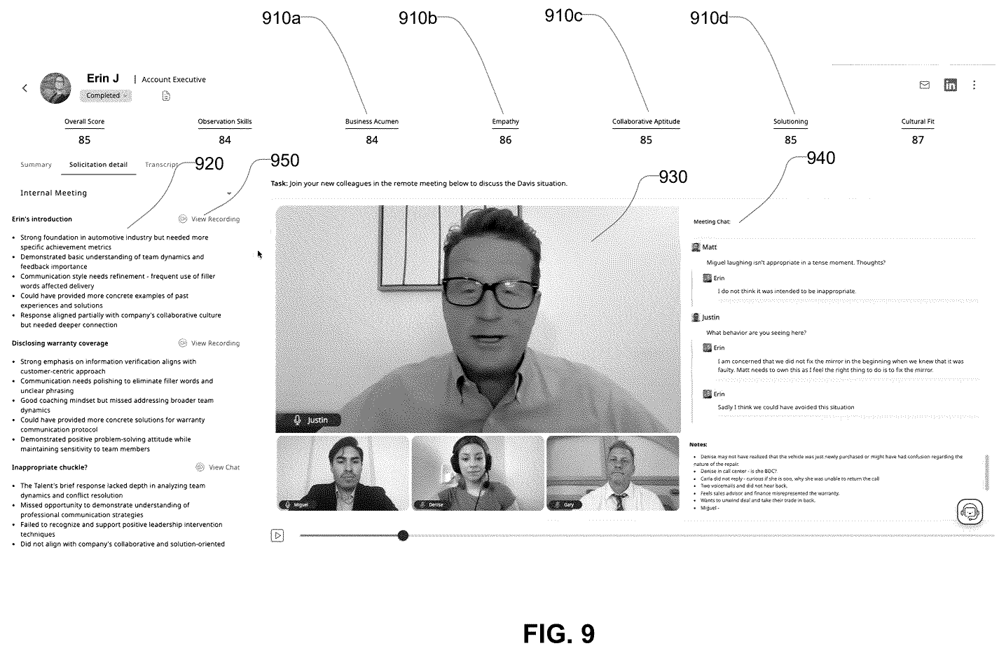

FIG. 9 shows a screenshot of a user interface displaying various scores of the user and details of a simulated meeting, according to an embodiment. As shown in FIG. 9, the various scores 910a, 910b, 910,c, 910d, and so on are displayed. For each score the user can drill down into details of how the score was determined and the relevant portions of user responses. The system also generates analysis for the candidate based on explanations 920 of the scores determined in relation to the responses provided by the candidate. According to an embodiment, the system generates the explanations 920 by providing the various responses to the machine learning-based language and requesting the machine learning-based language to generate the explanations 920. The system allows the user to inspect the relevant portions, for example, by viewing the relevant portions of the video segments 930 using the widget 950 or by viewing relevant portions of the chat 940 performed with the candidate.

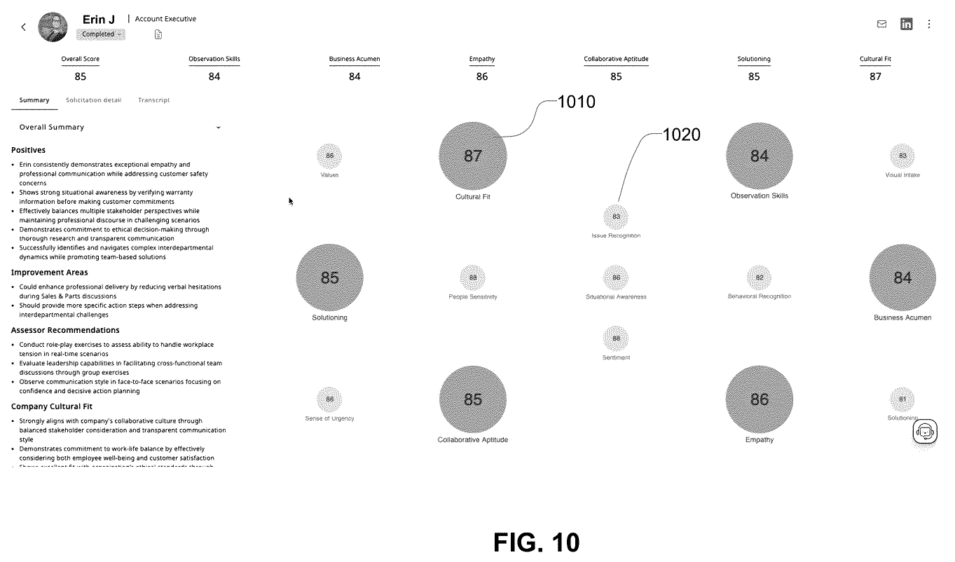

FIG. 10 shows a screenshot of a user interface displaying various scores and raw metrics and their relations, according to an embodiment. The system may display the various scores and raw metrics and their relations as a graph in which the nodes represent scores or raw metrics and edges connect two nodes if the two nodes are related. For example, an edge may connect a node representing a score with a node representing a raw metric if the raw metric was used to determine the score. The nodes 1010 representing scores may be displayed different from nodes 1020 representing raw metrics, for example, having different size or color. The color or size of a node may depend on the strength of the value of that node. For example, nodes with higher values of scores may be represented by different color or size compared to nodes with small values of scores. The user interface may further highlight relevant portions of the responses if a user selects a particular node representing a score or raw metric.

### Architecture of Computer

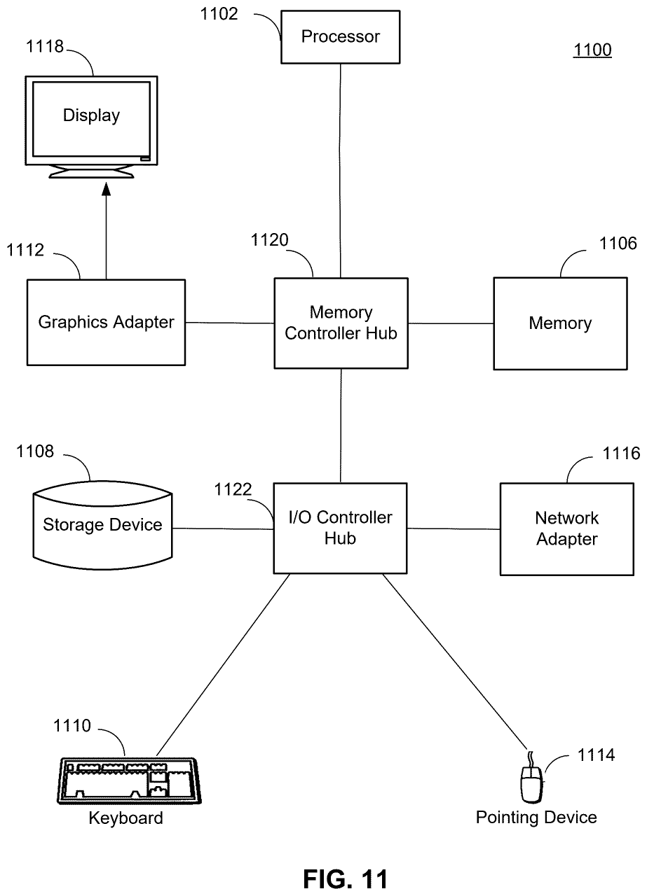

FIG. 11 is a high-level block diagram illustrating an example of a computer 1100 for use as one or more of the systems illustrated in FIG. 1, according to one embodiment. Illustrated are at least one processor 1102 coupled to a memory controller hub 1120, which is also coupled to an input/output (I/O) controller hub 1122. A memory 1106 and a graphics adapter 1112 are coupled to the memory controller hub 1122, and a display device 1118 is coupled to the graphics adapter 1112. A storage device 1108, keyboard 1110, pointing device 1114, and network adapter 1116 are coupled to the I/O controller hub. The storage device may represent a network-attached disk, local and remote RAID, or a SAN (storage area network). A storage device 1108, keyboard 1110, pointing device 1114, and network adapter 1116 are coupled to the I/O controller hub 1122. Other embodiments of the computer 1100 have different architectures. For example, the memory is directly coupled to the processor in some embodiments, and there are multiple different levels of memory coupled to different components in other embodiments. Some embodiments also include multiple processors that are coupled to each other or via a memory controller hub.

The storage device 1108 includes one or more non-transitory computer-readable storage media such as one or more hard drives, compact disk read-only memory (CD-ROM), DVD, or one or more solid-state memory devices. The memory holds instructions and data used by the processor 1102. The pointing device 1114 is used in combination with the keyboard to input data into the computer 1100. The graphics adapter 1112 displays images and other information on the display device 1118. In some embodiments, the display device includes a touch screen capability for receiving user input and selections. One or more network adapters 1116 couple the computer 1100 to a network. Some embodiments of the computer have different and/or other components than those shown in FIG. 11. For example, the online system can be comprised of one or more servers that lack a display device, keyboard, pointing device, and other components, while a client device acting as a requester can be a server, a workstation, a notebook or desktop computer, a tablet computer, an embedded device, or a handheld device or mobile phone, or another type of computing device. The requester to the online system also can be another process or program on the same computer on which the online system operates.

The computer 1100 is adapted to execute computer program modules for providing functionality described herein. As used herein, the term “module” refers to computer program instructions and/or other logic used to provide the specified functionality. Thus, a module can be implemented in hardware, firmware, and/or software. In one embodiment, program modules formed of executable computer program instructions are stored on the storage device, loaded into the memory, and executed by the processor.

### Additional Considerations

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above disclosure.

Some portions of this description describe the embodiments of the invention in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the invention may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a tangible computer readable storage medium or any type of media suitable for storing electronic instructions, and coupled to a computer system bus. Furthermore, any computing systems referred to in the specification may include a single processor or may be architectures employing multiple processor designs for increased computing capability.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention.

What is claimed is:

1. A computer-implemented method comprising:
retrieving a plurality of responses from a user based on the interactions with the user via a plurality of channels, the channels comprising a video channel and an interactive communication channel;
storing, in a database, a plurality of expected responses;
for each response from the plurality of responses, determining a plurality of raw metrics, each raw metric evaluating the user based on the response, comprising:
comparing the response received from the user with the expected responses stored in the database;
determining a plurality of scores based on the plurality of raw metrics, wherein each score is determined as a weighted aggregate of a set of raw metrics, each score evaluating the user;
configuring a second user interface for presenting the plurality of scores, the second user interface displaying associations between a particular score and portions of response determined to be relevant for determining at least a raw metric considered for evaluating the score; and
sending the second user interface for display via a second device.

2. The computer-implemented method of claim 1, wherein determining a raw metric based on a response comprises:
providing the response to trained neural network as input and executing the trained neural network to determine a value of the raw metric.

3. The computer-implemented method of claim 2, wherein the trained neural network is machine learning-based language model, the computer-implemented method further comprising:
generating one or more prompts for providing as input to the machine learning-based language model;
sending the one or more prompts to the machine learning-based language model; and
receiving one or more responses from execution of the machine learning-based language model, wherein a response comprises one or more of: a measure of value of a raw metric or information identifying a portion of the response considered for determining the raw metric.

4. The computer-implemented method of claim 1, wherein the response is received for a situation, wherein determining a raw metric based on a response comprises:
comparing a response received from the user with a plurality of expected responses associated with the situation, wherein each expected response is associated with a value for the raw metric;
selecting an expected response matching the response received from the user; and
determining a value of the response received from the user based on the value of the raw metric corresponding to the expected response that is matching.

5. The computer-implemented method of claim 4, wherein comparing the response with an expected response comprises:
storing, in a vector database, vector representations of expected responses;
generating a vector representation of the response received from the user; and
comparing the vector representation of the response received from the user with vector representations of the expected responses stored in the vector database based on a similarity metric.

6. The computer-implemented method of claim 1, wherein a channel is configured to send information using video segments and receive response of the user as live video stream.

7. The computer-implemented method of claim 1, wherein a channel is an interactive text communication channel, wherein sending information comprises sending a sequence of stored text communications in accordance with an execution plan of a simulated interaction.

8. A non-transitory computer readable storage medium storing instructions that when executed by one or more computer processors cause the one or more computer processors to perform steps comprising:
retrieving a plurality of responses from a user based on the interactions with the user via a plurality of channels, the channels comprising a video channel and an interactive communication channel;
storing, in a database, a plurality of expected responses;
for each response from the plurality of responses, determining a plurality of raw metrics, each raw metric evaluating the user based on the response, comprising:
comparing the response received from the user with the expected responses stored in the database;
determining a plurality of scores based on the plurality of raw metrics, wherein each score is determined as a weighted aggregate of a set of raw metrics, each score evaluating the user;
configuring a second user interface for presenting the plurality of scores, the second user interface displaying associations between a particular score and portions of response determined to be relevant for determining at least a raw metric considered for evaluating the score; and
sending the second user interface for display via a second device.

9. The non-transitory computer readable storage medium of claim 8, wherein determining a raw metric based on a response comprises:
providing the response to trained neural network as input and executing the trained neural network to determine a value of the raw metric.

10. The non-transitory computer readable storage medium of claim 9, wherein the trained neural network is machine learning-based language model, wherein the stored instructions further cause the one or more computer processors to perform steps comprising:
generating one or more prompts for providing as input to the machine learning-based language model;
sending the one or more prompts to the machine learning-based language model; and
receiving one or more responses from execution of the machine learning-based language model, wherein a response comprises one or more of: a measure of value of a raw metric or information identifying a portion of the response considered for determining the raw metric.

11. The non-transitory computer readable storage medium of claim 8, wherein the response is received for a situation, wherein determining a raw metric based on a response comprises:
comparing a response received from the user with a plurality of expected responses associated with the situation, wherein each expected response is associated with a value for the raw metric;
selecting an expected response matching the response received from the user; and
determining a value of the response received from the user based on the value of the raw metric corresponding to the expected response that is matching.

12. The non-transitory computer readable storage medium of claim 11, wherein comparing the response with an expected response comprises:
storing, in a vector database, vector representations of expected responses;
generating a vector representation of the response received from the user; and
comparing the vector representation of the response received from the user with vector representations of the expected responses stored in the vector database based on a similarity metric.

13. The non-transitory computer readable storage medium of claim 8, wherein a channel is configured to send information using video segments and receive response of the user as live video stream.

14. The non-transitory computer readable storage medium of claim 8, wherein a channel is an interactive text communication channel, wherein sending information comprises sending a sequence of stored text communications in accordance with an execution plan of a simulated interaction.

15. A computer system comprising:
one or more computer processors; and
a non-transitory computer readable storage medium storing instructions that when executed by the one or more computer processors cause the one or more computer processors to perform steps comprising:
retrieving a plurality of responses from a user based on the interactions with the user via a plurality of channels, the channels comprising a video channel and an interactive communication channel;
storing, in a database, a plurality of expected responses;
for each response from the plurality of responses, determining a plurality of raw metrics, each raw metric evaluating the user based on the response, comprising:
comparing the response received from the user with the expected responses stored in the database;
determining a plurality of scores based on the plurality of raw metrics, wherein each score is determined as a weighted aggregate of a set of raw metrics, each score evaluating the user;
configuring a second user interface for presenting the plurality of scores, the second user interface displaying associations between a particular score and portions of response determined to be relevant for determining at least a raw metric considered for evaluating the score; and
sending the second user interface for display via a second device.

16. The computer system of claim 15, wherein determining a raw metric based on a response comprises:
providing the response to trained neural network as input and executing the trained neural network to determine a value of the raw metric.

17. The computer system of claim 16, wherein the trained neural network is machine learning-based language model, wherein the stored instructions further cause the one or more computer processors to perform steps comprising:
generating one or more prompts for providing as input to the machine learning-based language model;
sending the one or more prompts to the machine learning-based language model; and
receiving one or more responses from execution of the machine learning-based language model, wherein a response comprises one or more of: a measure of value of a raw metric or information identifying a portion of the response considered for determining the raw metric.

18. The computer system of claim 15, wherein the response is received for a situation, wherein determining a raw metric based on a response comprises:
comparing a response received from the user with a plurality of expected responses associated with the situation, wherein each expected response is associated with a value for the raw metric;
selecting an expected response matching the response received from the user; and
determining a value of the response received from the user based on the value of the raw metric corresponding to the expected response that is matching.

19. The computer system of claim 18, wherein comparing the response with an expected response comprises:
storing, in a vector database, vector representations of expected responses;
generating a vector representation of the response received from the user; and
comparing the vector representation of the response received from the user with vector representations of the expected responses stored in the vector database based on a similarity metric.

20. The computer system of claim 15, wherein a first channel is configured to send information using video segments and receive response of the user as live video stream and a second channel is an interactive text communication channel, wherein sending information comprises sending a sequence of stored text communications in accordance with an execution plan of a simulated interaction.
